(19) United States
(12) Patent Application Publication
(10) Pub. No.: US 2026/0101465 A1
(43) Pub. Date: Apr. 9, 2026

(54) SERVER CLUSTER CONTAINER AND CONTAINERIZED SERVER CLUSTER APPARATUS

(71) Applicant: CANAAN CREATIVE CO., LTD., Beijing (CN)

(72) Inventors: Guanchao Zhao, Beijing (CN); Nan Li, Beijing (CN); Shishuang He, Beijing (CN); Zonghai Chen, Beijing (CN); Xiaogang Sun, Beijing (CN); Xiaoye Zhao, Beijing (CN); He Ying, Beijing (CN); Nangengh Zhang, Beijing (CN)

(21) Appl. No.: 19/479,528

(22) PCT Filed: Mar. 7, 2024
(86) PCT No.: PCT/CN2024/080555

§ 371 Date: Oct. 28, 2025

(30) Foreign Application Priority Data
Apr. 28, 2023 (CN) 202321025319.0
May 17, 2023 (CN) 202321196984.6

(51) Int. Cl. H05K 7/14

(52) U.S. Cl. CPC H05K 7/1492; H05K 7/1491

(57) ABSTRACT

Disclosed are a server cluster container and a containerized server cluster device. The server cluster container in the present application comprises a container body, a rack arranged in the container body, and an electronic control system, which is configured to connect to servers supported on the rack, wherein the electronic control system comprises a power distribution cabinet and a switch. The servers supported on the rack are electrically connected to the power distribution cabinet, and are in signal connection with the switch, thereby forming the containerized server cluster device with high-density deployment, high computational efficiency and flexible configuration.

### CROSS-REFERENCE TO RELATED APPLICATIONS

The present application claims priority to Chinese Patent Application No. 202321025319.0 filed on Apr. 28, 2023, and priority to Chinese Patent Application No. 202321196984.6 filed on May 17, 2023, and these patent applications are incorporated herein by reference for all purposes as if fully set forth herein.

### TECHNICAL FIELD

The present application relates to the field of computing devices, and specifically to a server cluster container and a containerized server cluster device.

### BACKGROUND

Container server clusters are a cluster device that integrates a plurality of servers, cooling systems, power supplies, control systems and other components in a single container. With the rapid growth in data processing demands, the container server clusters have gained significant attention due to their features such as ease of transportation and deployment.

How to lay out and wire a containerized server cluster in a container body and improve the working efficiency of the server cluster is a technical problem that needs to be solved by those skilled in the art.

### SUMMARY

Objectives of the present application are to provide a server cluster container and a containerized computer cluster device including this container, improving the working efficiency of a server cluster through a reasonable layout of a power distribution cabinet, a rack and a switch of the container.

In order to achieve the above objectives, the server cluster container of the present application includes a container body, and a rack disposed in the container body, and an electronic control system for connecting servers supported on the rack, the electronic control system including a power distribution cabinet and a switch. The servers supported on the rack are electrically connected to the power distribution cabinet, and are in signal connection with the switch, thereby forming the containerized server cluster device with high-density deployment, high computational efficiency and flexible configuration.

Regarding the above server cluster container, the container body includes a top corrugated plate and a top wiring conduit, the top wiring conduit is disposed in the container body, and at least a part of the top wiring conduit is located in a corrugated groove of the top corrugated plate. The present application makes full use of the characteristics of the plate material of the container body to lay out conduits, reducing spaces occupied by lines and conduits in the container body, freeing up part of a height space of the container body, and providing a possibility of improving the integration performance of the entire device.

Regarding the above server cluster container, the top wiring conduit includes a longitudinal conduit and a transverse conduit that are cross-distributed, the longitudinal conduit is at least partially located in the corrugated groove of the top corrugated plate, or the transverse conduit is at least partially located in the corrugated groove of the top corrugated plate. The longitudinal conduit or transverse conduit of the top wiring conduit are located in the corrugated groove of the top corrugated plate, which reduces a vertical space occupied by the longitudinal conduit or transverse conduit in the container body.

Regarding the above server cluster container, an extension direction of the longitudinal conduit is consistent with an extension direction of the corrugated groove, and the longitudinal conduit is disposed in the corrugated groove. While ensuring the strength of the container body, part or all of the longitudinal conduit of the top wiring conduit is disposed in the corrugated groove of the top corrugated plate, which greatly reduces the vertical space occupied by the entire top wiring conduit in the container body.

Regarding the above server cluster container, the top wiring conduit further includes a junction box connected to the longitudinal conduit and/or the transverse conduit, and the junction box is at least partially located in the corrugated groove. A volume of the junction box is relatively large. Disposing part or all of the junction box at a position where the corrugated groove is located can further reduce the vertical space occupied by the entire top wiring conduit in the container body.

Regarding the above server cluster container, the junction box is connected to an end of the longitudinal conduit, or the junction box is connected to an intersection of the longitudinal conduit and the transverse conduit, or the junction box is connected to an end of the transverse conduit. The junction box may be used for connection with various devices in the container body, such as illumination lamps, sensors, cameras, etc. Meanwhile, the junction box may also lead out a plurality of spare sockets, which are distributed on side walls and a top wall of the container body for connecting various powered devices.

Regarding the above server cluster container, the switches are disposed at two ends of the racks away from the power distribution cabinet, and signal lines of the servers supported on the racks are connected to the switches. The power distribution cabinet of the present application extends and distributes power lines from the middle to outer sides of the two ends, which stabilizes the power transmission and improves the overall working performance of the device. This avoids issues such as redundant power lines, unstable power supply, and signal attenuation due to unilateral extension of the power lines.

Regarding the above server cluster container, the rack includes a plurality of partition layers for supporting the servers, each correspondingly provided with at least one of the switches. The rack has a plurality of partition layers, each of which can support servers, and a switch is disposed corresponding to each partition layer.

Regarding the above server cluster container, signal lines of the servers supported on each of the partition layers are connected to at least one of the switches corresponding to the partition layer. The signal lines of the servers on each partition layer are respectively connected to a switch disposed corresponding to the partition layer, so that no winding is required, and the wiring is neat and clear.

Regarding the above server cluster container, the partition layer includes a cross beam provided with a cable management slot, through which the signal lines of the servers supported on the partition layer are connected to the switch. The cable management slot can avoid loose, dropped and entangled cables, reduce wire damage and thereby improving the device safety and production efficiency, which can also make the container body neater to provide convenience for staff's daily maintenance and management.

Regarding the above server cluster container, the partition layer includes a first cross beam and a second cross beam that are disposed at intervals in a horizontal direction, the first cross beam is provided with a first cable management slot, through which signal lines of a part of the servers supported on the partition layer are connected to the switch, and the second cross beam is provided with a second cable management slot, through which signal lines of the other part of the servers supported on the partition layer are connected to the switch. When a relatively large number of servers are disposed on the partition layer, the servers on the partition layer are divided into different parts to be connected to the switch through a plurality of cross beams and cable management slots disposed thereon, so as to avoid confusion caused by too many lines.

Regarding the above server cluster container, the rack includes upright rack bodies that disposed oppositely and a plurality of layered partitions connected between the upright rack bodies, and at least a part of the layered partitions is in a mesh shape. The layered partitions of the rack are in a mesh shape, and the mesh-shaped layered partitions will not completely block the servers supported thereon. That is to say, the mesh-shaped layered partitions provide a perspective for observing a working status of the servers placed thereon, which is beneficial to daily monitoring and maintenance.

Regarding the above server cluster container, the power distribution cabinet includes a side wall that is adjacent to the upright rack bodies and has a plurality of cable outlets, and the layered partitions include cross beams, at least one of the cable outlets are disposed corresponding to at least one of the cross beams. A power line leading out from each cable outlet of the power distribution cabinet can supply power to the servers on one of the partition layers of the rack.

Regarding the above server cluster container, the cable outlets are disposed corresponding to the cross beams lower than a height of the power distribution cabinet. That is to say, for the cross beams lower than the height of the power distribution cabinet, there are cable outlets as disposed correspondingly.

Preferably, the cable outlets are disposed in a one-to-one correspondence with the cross beams that are lower than the height of the power distribution cabinet, and the cable outlets and the cross beams that are in a one-to-one correspondence have the same vertical height. The power lines leading out from the cable outlets do not need to be bent along the height direction of the container body and can directly correspond to the cross beams of the layered partitions, so that the layout of the power lines is more compact and uncluttered, ensuring the safety and reliability of power supply.

Regarding the above server cluster container, a top of the power distribution cabinet has a top cable port disposed corresponding to the cross beam higher than the height of the power distribution cabinet. That is to say, for the cross beam higher than the height of the power distribution cabinet, there is a top cable port as disposed correspondingly.

Regarding the above server cluster container, the cable outlets and the corresponding cross beams are disposed in a staggered manner along a width direction of the container body. The power lines leading out from the cable outlets of the power distribution cabinet do not need to be bent along the width direction of the container body and can directly correspond to the cross beams of the layered partitions, which further reduces the possibility of occurrence of line damage, leakage and other safety issues that may be caused by bending the power lines, and can also reduce the length of the exposed power lines, making the inside of the container more uncluttered and facilitating the staff's inspection and maintenance.

Regarding the above server cluster container, the electronic control system further includes a plurality of power distributors disposed on the cross beams, and line input ends of the power distributors face a direction of the power distribution cabinet. The power lines leading out from the cable outlets of the power distribution cabinet extend horizontally along the cross beams, connect to the line input ends of the power distributors, and then can supply power to the servers through the power distributors, so that a power line wiring path can be extremely simplified.

Regarding the above server cluster container, the rack further includes an extension baffle disposed on an outer side of at least one of the layered partitions along a width direction of the container body, which increase a length of the rack along the width direction.

Regarding the above server cluster container, the layered partitions include high layered partitions higher than or equal to a set height and low layered partitions lower than the set height, and the extension baffle is disposed on an outer side of at least one of the high layered partitions. This set height is, for example, a height of maintenance personnel. That is to say, the extension baffle is disposed at a position higher than the height of the maintenance personnel, thereby expanding the support space of the rack without affecting the daily work of the maintenance personnel.

Regarding the above server cluster container, the extension baffle is disposed on an outer side of the high layered partition at a topmost layer, which increases the number of integrated servers based on the limited space and can improve the computing power of the containerized server cluster device.

Regarding the above server cluster container, the extension baffle includes a baffle beam, and the electronic control system further includes a power distributor disposed on the baffle beam. In the present application, the extension baffle increases the length of the layered partitions of the rack along the width direction of the container body, thereby increasing the number of integrated servers, and the baffle beam and the power distributor thereon are disposed to provide an electric power source for the servers integrated thereon.

Regarding the above server cluster container, the power distribution cabinet includes a side wall that is adjacent to the upright rack bodies and has a plurality of cable outlets, a top of the power distribution cabinet has a top cable port, and line input ends of the power distributors face a direction of the power distribution cabinet. The power lines leading out from the cable outlets and the top cable outlet are directly connected to the inlet terminals of the power distributors.

Regarding the above server cluster container, the rack further includes a device mounting portion located on a side of the rack away from the power distribution cabinet, which is used for mounting devices such as switches.

Regarding the above server cluster container, the device mounting portion is located on the upright rack body on a side of the rack away from the power distribution cabinet, and extends along the upright rack body in the shape of a slat, resulting in a simple structure and convenient connection.

Regarding the above server cluster container, the racks and the power distribution cabinet are disposed in a row along the length direction of the container body to form a device row, and the racks are symmetrically disposed on two sides of the power distribution cabinet. By providing a symmetrical configuration of the racks on the two sides of the power distribution cabinet, and still further, by configuring the switches on the two sides of the power distribution cabinet, the same number of servers with the same specifications can be arranged on the racks, so that the power lines or communication lines leading out of the power distribution cabinet to the two ends are evenly distributed and clearly routed, which makes it easy for staff to manage and maintain and can avoid troubles caused by too many and too long power lines or communication lines and complex wiring redundancy due to single-side cabling, thereby reducing maintenance manpower and device costs. Moreover, this can further ensure the overall counterweight balance of the container and increase the overall reliability of the device.

Regarding the server cluster container, the container body includes a first side heat dissipation long edge and a second side heat dissipation long edge that symmetrically extend along the length direction, and a maintenance passage is formed between the first side heat dissipation long edge and the device row. By means of the first side heat dissipation long edge and the second side heat dissipation long edge as disposed oppositely, an air flow is formed in the server cluster container of the present application, so as to dissipate heat from and cool the servers in the container body, resulting a simple structure, low cost and good heat dissipation effect. The maintenance passage between the first side heat dissipation long edge and the device row is spacious and smooth, which is used for the staff to conduct regular inspection, maintenance and upkeep for systems, devices, networks, and the like to ensure that they can normally operate, prevent failures and accidents, and improve the reliability and stability of the systems.

Regarding the above server cluster container, the power distribution cabinet includes a control and maintenance panel having a control switch and status display modules corresponding to each group of cooling structures, which is beneficial to the staff's manipulation and observation of the cooling structures at any time.

Regarding the above server cluster container, the power distribution cabinet includes a cabinet door, at least a part of the control and maintenance panel is integrated outside the cabinet door. The staff can check a working status of each cooling fan at any time without opening the cabinet door.

Regarding the above server cluster container, a position on the first side heat dissipation long edge corresponding to the top of the power distribution cabinet is provided with a cable inlet. The cable inlet directly corresponds to the top of the power distribution cabinet, and power cables are introduced through the cable inlet and connected to the power distribution cabinet, resulting in a direct path, shortening the length of the power cables inside and outside the container body, reducing the space occupied by the power cables in the container body, avoiding the accumulation and extension of a large number of large-volume power cables in the container body, and facilitating the staff's daily inspection, maintenance and upkeep work on the systems, devices and networks in the container body.

Regarding the above server cluster container, a cable support structure is disposed between the top of the power distribution cabinet and the cable inlet for supporting power cables introduced through the cable inlet and connected to the power distribution cabinet.

Regarding the above server cluster container, the cable support structure includes a cable tray for supporting the power cables and a hoisting structure for hoisting the cable tray to a top of the container body.

The containerized server cluster device of the present application includes a plurality of servers, which further includes the above server cluster container, and the servers are arranged and disposed on the rack and connected to the power distribution cabinet.

Regarding the above containerized server cluster device, a server located on a layered partition at a topmost layer of the rack is laid flat. In the present application, by laying the server flat, the number of integrated servers is increased, which can improve the computing power of the device.

Regarding the above containerized server cluster device, two rows of power distributors are present on the layered partition at the topmost layer of the rack, the server on the layered partition at the topmost layer of the rack is connected with one row of the power distributors at the topmost layer, and the servers on the remaining layered partitions are connected with the power distributors on the layered partitions at respective upper layers. That is to say, the layered partitions below the layered partition at the topmost layer form “up-down” connection relationships in which a power distributor on a layered partition at an upper layer is connected to servers on a layered partition at a lower layer. This is not only convenient to operate, but also can reduce damage to the power distributors caused by moisture and stains in the container body.

Regarding the above containerized server cluster device, it further includes a top-layer device status feedback means. During maintenance, the staff can be timely aware of a working status of the server located at the topmost layer.

Regarding the above containerized server cluster device, the top-layer device status feedback means is a reflective mirror observation means. The top-layer device status feedback means employs the reflective mirror observation means, which can achieve real-time monitoring of the server status by means of a status indicator light of the server itself without investing any software or hardware in the server. There may be one or more reflective mirror observation means.

Regarding the above containerized server cluster device, the reflective mirror observation means includes a plurality of feedback areas, each corresponding to at least one server located on the layered partition at the topmost layer. Each of the feedback areas corresponds to at least one server disposed on the layered partition at the topmost layer, and feeds back a working status of the server in real time, which facilitates timely processing by the staff and ensures the working efficiency of the device.

The following detailed description of the present application will be made in conjunction with the drawings and specific embodiments, but is not intended to limit the present application.

### BRIEF DESCRIPTION OF THE DRAWINGS

FIG. 1 is a perspective structural diagram of an embodiment of a server cluster container of the present application;

FIG. 2 is a perspective view of the internal structure of an embodiment of a server cluster container of the present application (with a top plate and two side plates of the container body not shown);

FIG. 3 is a perspective view of the internal structure of an embodiment of a server cluster container of the present application (with a top plate and two side plates of the container body not shown);

FIG. 4 is a front view of an embodiment of a container power distribution information bracket arrangement of the present application;

FIG. 5 is a perspective structural diagram of an embodiment of a rack of a server cluster container of the present application;

FIG. 6 is a perspective view of the internal structure of an embodiment of a server cluster container of the present application (with a top plate and four side plates of the container body not shown);

FIG. 7 is a perspective structural diagram of an embodiment of a power distribution cabinet of a server cluster container of the present application;

FIG. 8 is a partial enlarged view of FIG. 6;

FIG. 9 is a side view of an embodiment of a rack of a server cluster container of the present application;

FIG. 10 is a partial enlarged view of FIG. 5;

FIG. 11 is a top view of an embodiment of a server cluster container of the present application (with a top plate of the container body not shown);

FIG. 12 is a side view of an embodiment of a server cluster container of the present application;

FIG. 13 is a partial enlarged view of an embodiment of a server cluster container of the present application (with a cable tray and baffle rods shown);

FIG. 14 is a partial view of a top wiring conduit observed upward from the container body of an embodiment of a server cluster container of the present application;

FIG. 15 is a partial view of an embodiment of a server cluster container of the present application with a top wiring conduit shown;

FIG. 16 is a structural perspective view of a top wiring conduit of an embodiment of a server cluster container of the present application;

FIG. 17 is a partial cutaway view of an embodiment of a server cluster container of the present application as taken along a direction of a longitudinal corrugated groove of the container body;

FIG. 18 is a perspective structural diagram of an embodiment of a power distributor in a server cluster container of the present application;

FIG. 19 is a perspective structural diagram of another embodiment of a power distributor in a server cluster container of the present application; and

FIG. 20 is an enlarged view of the portion Q in FIG. 19.

### Reference Numerals

1, 2, 3: Server cluster container
11: Corner post
12: Bottom side beam
13: Top side beam
14: Corner member
100: Container body
110: First side heat dissipation long edge
120: Second side heat dissipation long edge
130: First side short edge
140: Second side short edge
160: Top corrugated plate
161: Longitudinal corrugated groove
200, 200a, 200b, 200c, 200d: Rack
201a, 202a, 201b, 202b: Partition layer
210: Upright rack body
220, 220a, 220b, 220c, 220d, 220e, 220f, 220g: Layered partition
221, 221b1, 221b2, 221b3, 221b4, 221b5: Cross beam
230: Extension baffle
231: Baffle beam
240: Cable management slot
250: Device mounting portion
310, 310a, 310b: Power distribution cabinet
311: Side wall
311b, 311b1, 311b2, 311b3, 311b4, 311b5: Cable outlets
312: Top cable port
313: Control switch
314: Status display module
315: Cabinet door
320, 320a, 320b, 320a1, 320a2: Switch
330, 331, 332, 333, 334, 335, 330a1, 330a2, 330b, 330c, 330d, 330e, 330f: Power distributor
400: Device row
500: Maintenance passage
600: Door leaf
700: Closed wall
802: Cable inlet
803: Cable tray
804: Baffle rod
900: Cooling structure
1000: Top wiring conduit
1010: Longitudinal conduit
1020: Transverse conduit
1030: Junction box
S: Container power distribution information bracket arrangement
A, B, C, D: End
11: Power distributor
111: Socket
112: Indicator light
113: line entry hole
114: Anti-disconnect structure
115: Through hole

### DETAILED DESCRIPTION

The following describes the technical solutions of the present application in detail in conjunction with the drawings and specific embodiments so as to further understand the objectives, solutions and effects of the present application, but not to limit the scope of protection of the appended claims of the present application.

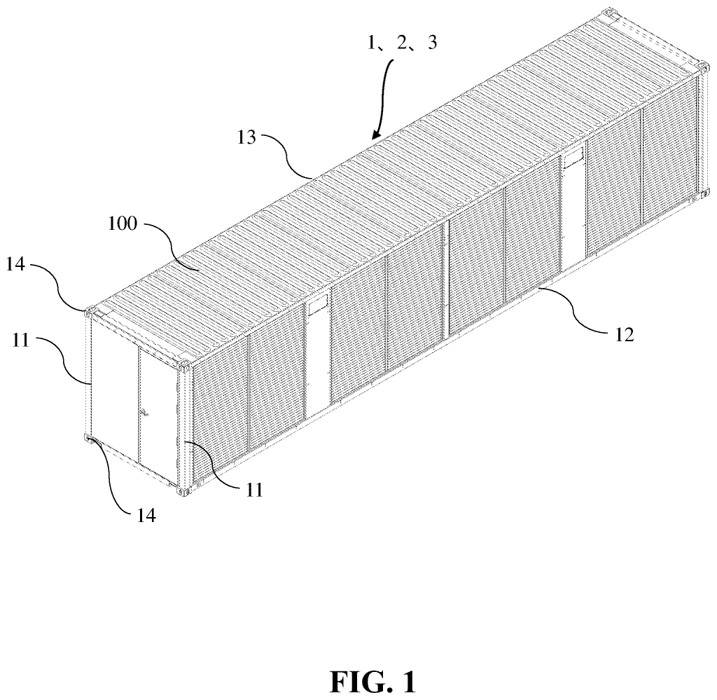

Currently, containerized servers have become a mainstream device in the computing device industry. A server cluster container 1 of some embodiments of the present application is used for loading and integrating a plurality of server devices to form a containerized server cluster device. As shown in FIGS. 1 to 3, FIGS. 2 and 3 respectively show internal views of a server cluster container of some embodiments of the present application. For ease of observation, parts of the container body such as a top plate and two side plates are not shown. The server cluster container 1 of some embodiments of the present application includes a container body 100, a rack 200 and an electronic control system, wherein the rack 200 and the electronic control system are respectively disposed in the container body 100, the rack 200 is used for supporting a plurality of servers, and the electronic control system connects the plurality of servers supported on the rack 200 to provide services such as power distribution and communication for the servers.

The electronic control system includes a power distribution cabinet 310 and a switch 320, which are connected with the servers supported on the rack 200, respectively. The racks 200 are disposed on two sides of the power distribution cabinet 310, and the switches 320 are disposed at ends of the racks 200 away from the power distribution cabinet 310.

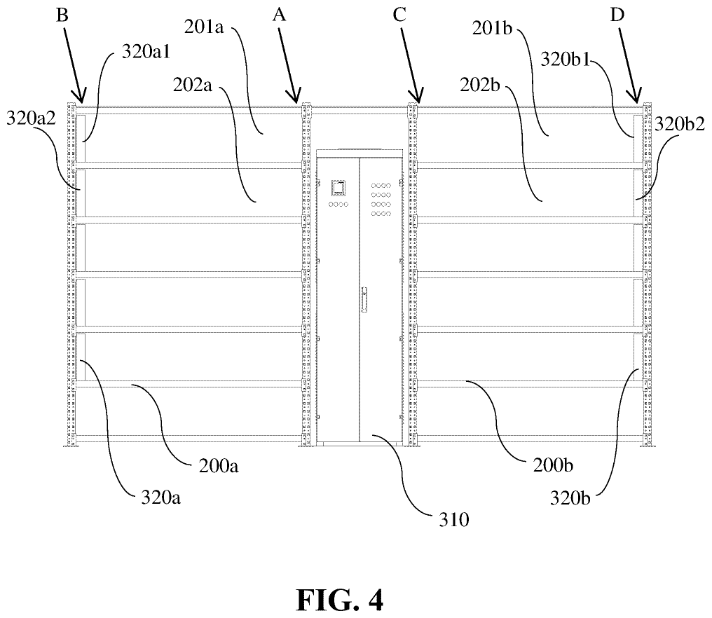

In some embodiments of the present application, the racks 200 are configured to be disposed on the two sides of the power distribution cabinet 310. In terms of a rack 200a on the left side of the power distribution cabinet 310 in FIG. 4, the rack 200a has an end A close to the power distribution cabinet 310 and an opposite end B away from the power distribution cabinet 310, and a switch 320a is disposed at the end B of the rack 200a. In terms of a rack 200b on the right side of the power distribution cabinet 310 in FIG. 4, the rack 200b has an end C close to the power distribution cabinet 310 and an opposite end D away from the power distribution cabinet 310, and a switch 320b is disposed at the end D of the rack 200b.

Power lines of the power distribution cabinet 310 extend and are distributed to the two sides in opposite directions, which are respectively connected with the servers on the racks 200 on the two sides. The power lines extending and leading out from the power distribution cabinet 310 to the left side are connected with the servers on the rack 200a on the left side, and the power lines extending and leading out from the power distribution cabinet 310 to the right side are connected with the servers on the rack 200b on the right side.

Communication lines of the switches 320 extend and are distributed from the two sides toward the middle, which are respectively connected with the servers on the racks 200. The communication lines of the switch 320a extend and lead out to the right side and are connected with the servers on the rack 200a in sequence, and the communication lines of the switch 320b extend and lead out to the left side and are connected with the servers on the rack 200b in sequence.

The power distribution cabinet 310 is used, for example, to supply power for the entire system, and includes components such as a main power input, a power management unit, a battery pack, and a UPS (uninterruptible power supply). The switch 320 connects a plurality of servers and establishes communication links between different devices, so that they can transmit data and information to each other, so that they can communicate and work collaboratively in one and the same network. In addition, the switch 320 may also provide certain network security, which, for example, may filter illegal data packets to prevent network attacks, data leakage and other issues.

In some embodiments of the present application, by configuring the racks 200 to be disposed on the two sides of the power distribution cabinet 310, and the switches 320 to be disposed at the ends of the racks 200 away from the power distribution cabinet 310, the power distribution cabinet 310 extends and distributes the power lines from the middle to the outer sides of the two ends, and the switches 320 extend and distribute the communication lines from the two ends to the inner sides, which achieves stable power and data transmission, and improves the overall working performance of the device. Moreover, the power lines and communication lines are routed independently of each other, and there will be no electromagnetic interference issue caused by crossing of the power lines and communication lines.

In some embodiments, the rack includes a plurality of partition layers for supporting servers, each correspondingly provided with at least one switch. Exemplarily, signal lines of the servers supported on each of the partition layers are connected to at least one of the switches corresponding to the partition layer.

In some embodiments, the partition layer includes a cross beam provided with a cable management slot (one, two, or more cable management slots), through which the signal lines of the servers supported on the partition layer are connected to the switch.

Exemplarily, the partition layer includes a first cross beam and a second cross beam that are disposed at intervals in a horizontal direction, the first cross beam is provided with a first cable management slot, through which signal lines of a part of the servers supported on the partition layer are connected to the switch, and the second cross beam is provided with a second cable management slot, through which signal lines of the other part of the servers supported on the partition layer are connected to the switch.

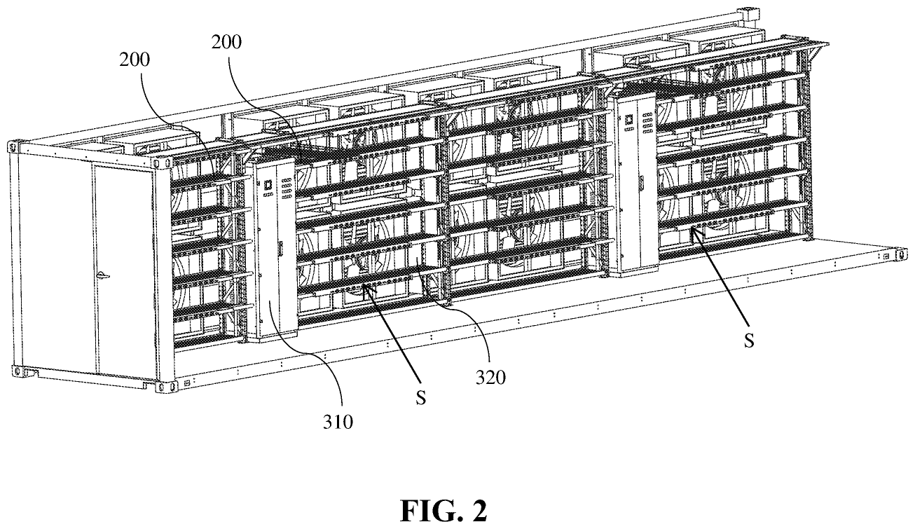

As shown in FIGS. 2 to 4, the switches 320 in the server cluster container 1 of some embodiments of the present application are disposed vertically and disposed at the partition layers of the racks 200. The switches 320 located at each partition layer of a rack are respectively connected with the servers supported at the partition layer. In detail, the switches 320a at the B end of each partition layer of the rack 200a are respectively connected with the servers supported at the partition layer of the rack 200a where they are located, and the switches 320b at the D end of each partition layer of the rack 200b are respectively connected with the servers supported on the partition layer of the rack 200b where they are located. In more detail, by means of example, a switch 320a1 is disposed at the B end of the partition layer 201a of the rack 200a, a plurality of servers are arranged in sequence at the partition layer 201a, and communication lines leading out of the switch 320a1 are respectively connected with the plurality of servers at the partition layer 201a. A switch 320a2 is disposed at the B end of the partition layer 202a of the rack 200a, a plurality of servers are arranged in sequence at the partition layer 202a, and communication lines leading out of the switch 320a2 are respectively connected with the plurality of servers at the partition layer 202a. A switch 320b1 is disposed at the D end of the partition layer 201b of the rack 200b, a plurality of servers are arranged in sequence at the partition layer 201b, and communication lines leading out of the switch 320b1 are respectively connected with the plurality of servers at the partition layer 201b. A switch 320b2 is disposed at the D end of the partition layer 202b of the rack 200b, a plurality of servers are arranged in sequence at the partition layer 202b, and communication lines leading out of the switch 320b2 are respectively connected with the plurality of servers at the partition layer 202b.

In some embodiments of the present application, the switches 320 are disposed vertically, which fully utilizes the space in the width direction of the racks 200 and increases the accommodating space for the servers. The switches 320 at the partition layers correspond to and are connected with the servers at the partition layers, which simplifies the arrangement of the communication lines, reduces the length of the communication lines, reduces signal attenuation and interference, and improves the speed and stability of data transmission.

It should be noted that the above electronic control system further includes air conditioning function, cabinet power management function, remote monitoring function and the like, which ensure the normal operation and management of the server container through collaboration among various components. The air conditioning function part includes an air conditioning controller, a compressor, a fan and other components, which are used for maintaining a temperature and humidity inside the server container; the cabinet power management function part is used for monitoring and managing a power supply of each cabinet, including powering on and off, restarting, monitoring power consumption, etc., the remote monitoring function part is used for remotely monitoring a status of the server container, including collecting and analyzing information such as temperature, humidity, power consumption, and network connection.

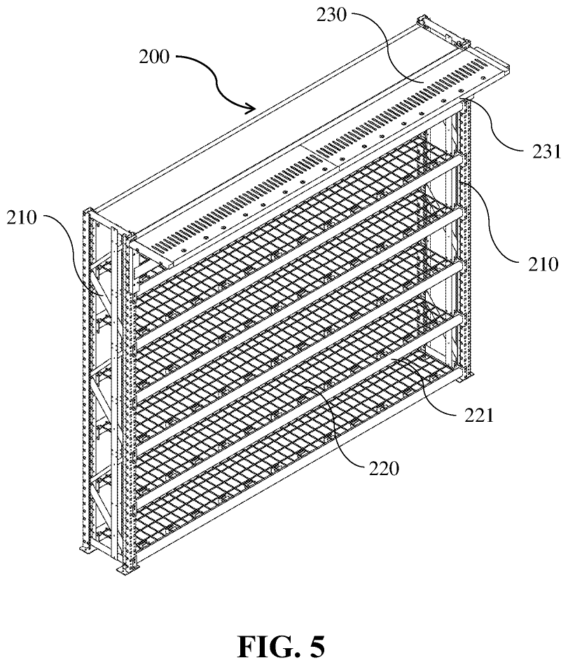

In an embodiment of the server cluster container of some embodiments of the present application, as shown in FIG. 5, the rack 200 includes upright rack bodies 210 that are disposed oppositely and layered partitions 220 that are connected between the oppositely disposed upright rack bodies 210. It may be understood that each partition layer is composed of parts of the upright rack bodies 210 where this partition layer is located and a layered partition 220, and the overall upright rack bodies 210 and a plurality of layered partitions 220 constitute a plurality of partition layers of the rack 200. Cross beams of the partition layers are actually disposed on the layered partitions 220.

The upright rack bodies 210 are provided with a plurality of height adjusting portions, for example, and the layered partitions 220 can be connected with the plurality of height adjusting portions of the upright rack bodies 210 to achieve the purpose of adjusting the height of the partition layers of the rack 200 and adapt to supporting of the servers at different heights. The height adjusting portions of the upright rack bodies 210 may be, for example, in the form of a hook, a slot, a mounting hole, etc., and the layered partitions 220 have structures disposed corresponding to the height adjusting portions.

The layered partitions 220 of the rack 200 of some embodiments of the present application are in a mesh shape, and the mesh-shaped layered partitions 220 will not completely block the servers supported thereon. That is to say, the mesh-shaped layered partitions 220 provide a perspective for observing a working status of the servers placed thereon, which is beneficial to daily monitoring and maintenance.

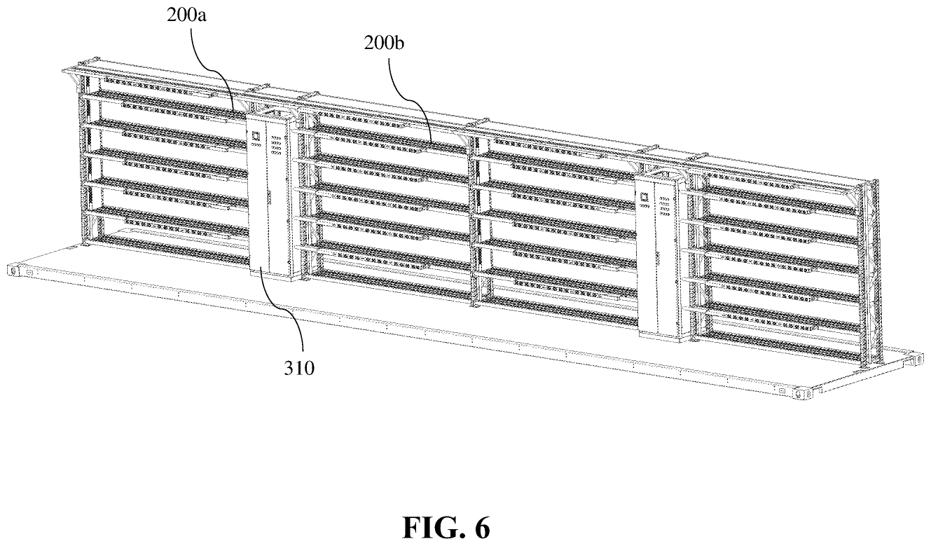

With reference to FIGS. 5 to 8, the power distribution cabinet 310 includes a side wall 311 disposed adjacent to an upright rack body 210 of a rack 200. The power distribution cabinet 310 has side walls 311 on the two sides, and the side walls 311 on the two sides are adjacent to the respective upright rack bodies 210 of the racks 200 on the two sides. As shown in FIG. 6, the racks 200a and 200b are respectively configured on the two sides of the power distribution cabinet 310. The side wall 311 on the left side of the power distribution cabinet 310 is adjacent to an upright rack body of the rack 200a, and the side wall 311 on the right side of the power distribution cabinet 310 is adjacent to an upright rack body of the rack 200b.

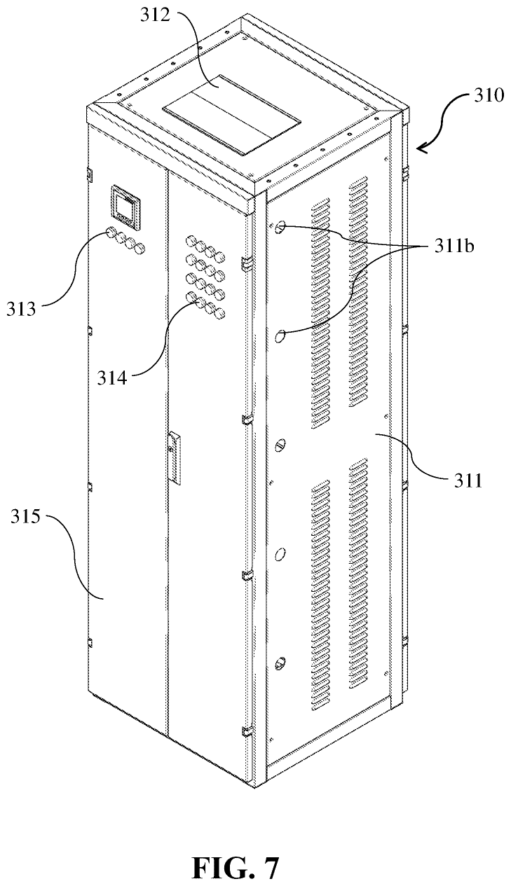

As shown in FIG. 7, the side wall 311 has a plurality of cable outlets 311b for allowing the power lines to lead out of the power distribution cabinet 310. As shown in FIG. 5, the layered partitions 220 of the rack 200 include cross beams 221. The cable outlets 311b on the side wall 311 of the power distribution cabinet 310 are disposed corresponding to the cross beams 221 of the layered partitions 220 of the rack 200. Preferably, the cable outlets 311b on the side wall 311 of the power distribution cabinet 310 are disposed in a one-to-one correspondence with the cross beams 221 of the layered partitions 220 of the rack 200.

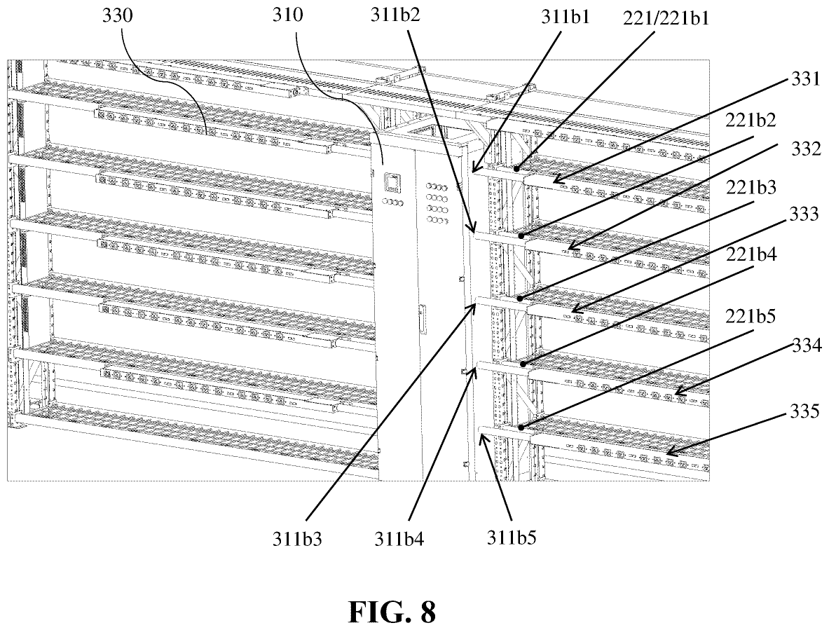

As shown in FIGS. 7 and 8, taking the right side of the power distribution cabinet 310 as an example, the cable outlets 311b on the side wall 311 of the power distribution cabinet 310 correspond to cross beams 221b of the rack 200b on the right side. In detail, the side wall 311 of the power distribution cabinet 310 located on the right side has cable outlets 311b1, 311b2, 311b3, 311b4 and 311b5, and the rack 200b has cross beams 221b1, 221b2, 221b3, 221b4 and 221b5. Accordingly, the cable outlet 311b1 is disposed corresponding to the cross beam 221b1, the cable outlet 311b2 is disposed corresponding to the cross beam 221b2, the cable outlet 311b3 is disposed corresponding to the cross beam 221b3, the cable outlet 311b4 is disposed corresponding to the cross beam 221b4, and the cable outlet 311b5 is disposed corresponding to the cross beam 221b5. A power line leading out from each cable outlet can supply power to the servers on one of the partition layers of the rack. The correspondence between the cable outlets on the left side wall 311 of the power distribution cabinet 310 and the cross beams of the rack 200a on the left side is the same as the above correspondence between the cable outlets on the right side wall 311 of the power distribution cabinet 310 and the cross beams of the rack 200b on the right side.

It should be noted that the above is merely an example. In some embodiments, there is also a situation where one cable outlet is disposed corresponding to a plurality of cross beams. That is to say, a power line leading out of the one cable outlet supplies power to servers at a plurality of partition layers, or a cable outlet may also lead out at a top end of the power distribution cabinet, which are all within the scope of protection of the present application.

Preferably, the cable outlets and the cross beams that are in a one-to-one correspondence have the same vertical height. As shown in FIG. 8, a vertical height of the cable outlet 311b1 is the same as a vertical height of the cross beam 221b1, a vertical height of the cable outlet 311b2 is the same as a vertical height of the cross beam 221b2, a vertical height of the cable outlet 311b3 is the same as a vertical height of the cross beam 221b3, a vertical height of the cable outlet 311b4 is the same as a vertical height of the cross beam 221b4, and a vertical height of the cable outlet 311b5 is the same as a vertical height of the cross beam 221b5. The power lines leading out from the cable outlets do not need to be bent along the height direction of the container body 100 and can directly correspond to the cross beams of the layered partitions, so that the layout of the power lines is more compact and uncluttered, ensuring the safety and reliability of power supply.

Further, as shown in FIG. 8, the cable outlets 311 and the cross beams 221 that are in a one-to-one correspondence are disposed in a staggered manner along a width direction of the container body 100. That is to say, the power lines leading out from the cable outlets 311 do not need to be bent along the width direction of the container body 100 either, and can directly correspond to the cross beams 221 of the layered partitions 220, which further reduces the possibility of occurrence of line damage, leakage and other safety issues that may be caused by bending the power lines, and can also reduce the length of the exposed power lines, making the inside of the container more uncluttered and facilitating staff's inspection and maintenance.

The electronic control system further includes a plurality of power distributors 330, which are transversely disposed on the cross beams 221 of the layered partitions 220 of the racks 200, respectively, and line input ends of the power distributors 330 are opposite to the corresponding cable outlets 311b of the power distribution cabinet 310. In detail, as shown in FIG. 8, taking the right side of the power distribution cabinet 310 as an example, power distributors 331 to 335 are transversely disposed on the cross beams 221b1 to 221b5 of the rack 200b, respectively. That is to say, the power distributor 331 is transversely disposed on the cross beam 221b1, with its line input end on the left side, namely opposite to the cable outlet 311b1; the power distributor 332 is transversely disposed on the cross beam 221b2, with its line input end also on the left side, namely opposite to the cable outlet 311b2; the power distributor 333 is transversely disposed on the cross beam 221b3, with its line input end opposite to the cable outlet 311b3; the power distributor 334 is transversely disposed on the cross beam 221b4, with its line input end opposite to the cable outlet 311b4; and the power distributor 335 is transversely disposed on the cross beam 221b5, with its line input end opposite to the cable outlet 311b5.

In related technologies, each power distributor 330 is provided with a switch to control power on or off. In some embodiments, the power distribution cabinet 310 is provided with a switch module for controlling each power distributor 330, and the switch module achieves independent control of each power distributor 330. For example, the switch module controls the power on or off of each power distributor 330. When a certain power distributor 330 needs to be maintained or servers connected to a certain power distributor 330 need to be powered off for maintenance, it is only necessary to use the switch module to power off the power of the power distributor 330 alone, which facilitates maintenance and improves safety. Furthermore, since the switch modules are centrally provided in the power distribution cabinet 310, the centralized control of all the power distributors 330 can be achieved, which is convenient for operation. For example, when a plurality of power distributors 330 need to be turned off or on, there is no need to separately walk near the respective power distributors 330 for operation.

The power line leading out from the cable outlet 311b1 of the power distribution cabinet 310 extends horizontally along the cross beam 221b1, connects to the line input end of the power distributor 331, and then can supply power to the servers through the power distributor 331. The power line leading out from the cable outlet 311b2 extends horizontally along the cross beam 221b2, connects to the line input end of the power distributor 332, and then can supply power to the servers through the power distributor 332. The power line leading out from the cable outlet 311b3 extends horizontally along the cross beam 221b3, connects to the line input end of the power distributor 333, and then can supply power to the servers through the power distributor 333. The power line leading out from the cable outlet 311b4 extends horizontally along the cross beam 221b4, connects to the line input end of the power distributor 334, and then can supply power to the servers through the power distributor 334. The power line leading out from the cable outlet 311b5 extends horizontally along the cross beam 221b5, connects to the line input end of the power distributor 335, and then can supply power to the servers through the power distributor 335.

In an embodiment of the server cluster container 1 of some embodiments of the present application, as shown in FIG. 5, the rack 200 further includes an extension baffle 230 disposed on an outer side of an uppermost layered partition 220 along the width direction of the container body 100.

Due to the limited space in the container body 100, there is a situation where a server cannot be placed normally on the layered partition at the uppermost layer of the rack 200. That is to say, a distance from the layered partition 220 at the uppermost layer of the rack 200 to a ceiling of the container body 100 cannot accommodate a server that is placed upright. By disposing the extension baffle 230 connected to the outer side of the layered partition 220 at the uppermost layer along the width direction of the container body 100, some embodiments of the present application achieve an increased length of the layered partition 220 at the uppermost layer of the rack 200 along the width direction of the container body 100 to enable a server to be laid flat thereon, and an increased number of integrated servers, which can improve the computing power of the device.

With reference to FIGS. 5, 8 and 9, the extension baffle 230 includes a baffle beam 231, on which the power distributor 330 is transversely disposed. The side face 311 of the power distribution cabinet 310 may be provided with a cable outlet corresponding to the baffle beam 231, and a line input end of the power distributor 330 disposed transversely on the baffle beam 231 faces a direction of the cable outlet. A power line leading out from the cable outlet on the side face 311 of the power distribution cabinet 310 extends along the baffle beam 231 and is connected to the power distributor 330.

The extension baffle 230 of the rack 200 of the present application is not limited to being disposed on the layered partition at the uppermost layer. In some embodiments, the extension baffle 230 extends horizontally out from the layered partitions 210 at any one or more positions so as to increase the length of the rack 200 along the width direction. Outer sides of the layered partitions 210 and/or the extension baffle 230 are provided with the power distributors.

In some embodiments of the present application, the layered partitions 210 include high layered partitions higher than or equal to a set height and low layered partitions lower than the set height, and the extension baffle 230 is disposed on an outer side of a high layered partition. This set height is, for example, a height of maintenance personnel. That is to say, the extension baffle 230 is disposed at a position higher than the height of the maintenance personnel, thereby expanding the support space of the rack 200 without affecting the daily work of the maintenance personnel.

In some embodiments, a height of the power distribution cabinet 310 is lower than a height of the rack 200. That is to say, the side face 311 of the power distribution cabinet 310 is not adjacent to the layered partition at the uppermost layer of the rack 200. In this case, as shown in FIG. 7, the top of the power distribution cabinet 310 has a top cable port 312 for leading out a power line from the top of the power distribution cabinet 310. The power line leading out from the top of the power distribution cabinet 310 is connected to the line input end of the power distributor 330 on the baffle beam 231 so as to provide power to the server disposed at the topmost layer of the rack 200.

In other embodiments, if a height of the power distribution cabinet 310 is relatively low, a plurality of layered partitions 220 are located above the power distribution cabinet 310, and the form of leading power lines out from the top of the power distribution cabinet 310 may be applied to them all, which likewise meets the arrangement requirement of minimizing the power lines. That is to say, the power lines leading out from the top of the power distribution cabinet 310 are connected to the line input ends of the power distributors 330 on the cross beams 221 of the layered partitions 220 at one or several upper layers of the rack 200, so as to provide power for the servers disposed on the layered partitions at the one or several upper layers of the layered partitions 220. In some embodiments of the present application, the power lines leading out from the top cable port 312 of the power distribution cabinet 310 are connected to two topmost power distributors 330 on the rack 200 through a corrugated conduit.

The above cross beam 221 and the baffle beam 231 refer to partial structures located at the layered partition 220 and the extension baffle 230, which have wiring conduits for routing and organizing signal cables connected with each server, and have a function of strengthening the supporting strength of the components at the same time. When the supporting strength of the components is sufficient, they may also refer only to structures at positions outside the layered baffle 220 and the extension baffle 230.

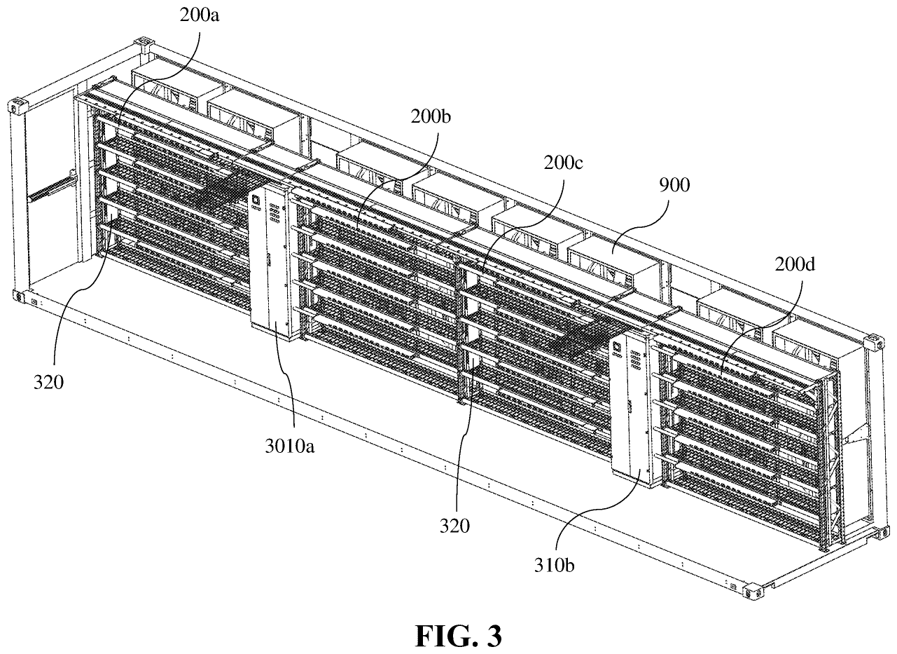

In an embodiment of the server cluster container 1 of some embodiments of the present application, as shown in FIGS. 2 and 3, the rack 200 and the power distribution cabinet 310 are disposed in a row along the length direction of the container body 100, making full use of a space inside the container body 100, with the racks 200 symmetrically configured on two sides of the power distribution cabinet 310.

By providing a symmetrical configuration of the racks 200 on the two sides of the power distribution cabinet 310, and still further, by configuring the switches 320 on the two sides of the power distribution cabinet 310, the same number of servers with the same specifications can be arranged on the racks 200, so that the power lines and communication lines leading out of the power distribution cabinet 310 and the switches 320 to the two ends and to the inner sides are evenly distributed and clearly routed, which makes it easy for staff to manage and maintain.

In this embodiment, as shown in FIG. 3, one rack 200a and one rack 200b are configured on the two sides of the power distribution cabinet 310a, respectively. The racks 200a and 200b have the same specifications, or in other words, the racks 200a and 200b have the same length, width, and height so as to have the ability to support the same number of servers with the same specifications.

It should be noted that the “one” rack here does not refer to one in the physical sense, but means that the racks on the two sides of the power distribution cabinet have the same specifications and the same ability to support servers, so that the power distribution cabinet evenly supplies power to the two sides. The racks on the two sides of the power distribution cabinet may also be connected to each other to form an integrated whole.

In other embodiments, the two sides of the power distribution cabinet 310 may be symmetrically configured with two or more racks 200 having the same number and specifications, so as to ensure that the power distribution cabinet 310 evenly routes lines and transmits power to servers on the racks in directions of the two sides. Further, the switches 320 are symmetrically configured at ends of the racks 200a and 200b away from the power distribution cabinet 310, so as to ensure that the power distribution cabinet 310 evenly leads lines out and performs communication to the servers on the racks on the two sides.

One power distribution cabinet 310 along with racks 200 and switches 320 symmetrically disposed on two sides serves as a container power distribution information bracket arrangement S, as shown in FIG. 4. Of course, the container power distribution information bracket arrangement S may also include matching accessories such as power lines, communication lines, etc.

In the embodiments shown in FIGS. 2 and 3, two container power distribution information bracket arrangements S are disposed in the container body 100. That is to say, two sides of a power distribution cabinet 310a are respectively configured with the racks 200a and 200b having the same specifications, and two sides of a power distribution cabinet 310b are respectively configured with racks 200c and 200d having the same specifications. Preferably, the racks 200a, 200b, 200c, and 200d have the same specifications, so that balance can be achieved in both power and communication line distribution and weight distribution. Further, the switches 320 are symmetrically configured at ends of the racks 200a and 200b away from the power distribution cabinet 310a, and at ends of the racks 200c and 200d away from the power distribution cabinet 310b.

The two container power distribution information bracket arrangements S are arranged side by side in a row. On the premise of ensuring the reliability of electrical control measures such as power distribution and communication, the number of configurable servers is multiplied, and the computing power of the containerized server cluster device is multiplied. When the computing power of the containerized server cluster device is increased, requests and tasks can be processed faster, thereby improving response speed and processing efficiency, supporting the processing of large amounts of data and more complex applications, and meeting higher performance requirements.

Moreover, the rack 200 and the power distribution cabinet 310 are fixed to each other, and the rack 200 and the switch 320 are fixed to each other. Mutual fixation between the rack 200 and the power distribution cabinet 310, as well as between the rack 200 and the switch 320, may be performed by using, for example, connectors, thereby making the structure firmer. In a process of long-distance transportation of the container, due to the influence of roads, weather, human factors, etc., the container may be subject to impact, tilting, or shaking, resulting in damage to goods. The server cluster container 1 of some embodiments of the present application provides stable fixation of the rack 200, the power distribution cabinet 310 and the switch 320 inside the container body 100, as well as mutual fixation between the rack 200 and the power distribution cabinet 310 and between the rack 200 and the switch 320, making long-distance transportation more stable and safer.

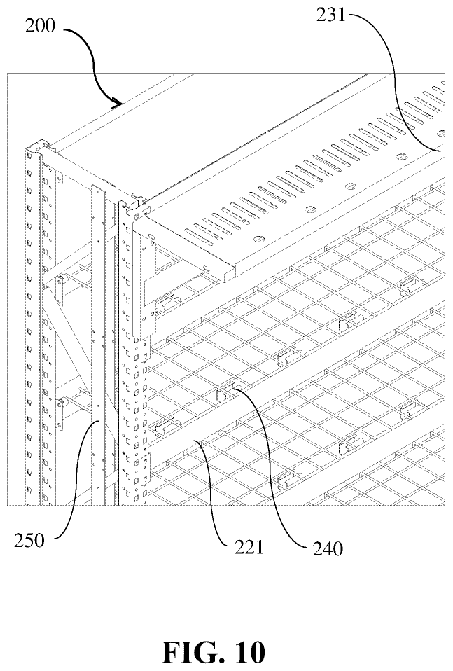

As shown in FIG. 10, the rack 200 includes cable management slots 240 including L-shaped clips that are disposed oppositely for routing and storing communication lines and other cables. The cable management slots 240 are, for example, disposed at intervals along the cross beam 221 or the baffle beam 231 to neatly fix the cables in the cable management slots 240. The cable management slots 240 can avoid loose, dropped and entangled cables, reducing wire damage and thereby improving the device safety and production efficiency, which can also make the container body 100 tidier to provide convenience for the staff's daily maintenance and management.

Further, the rack 200 further includes a device mounting portion 250 for mounting the switch 230, for example, which, of course, may also be used for mounting other devices and components that need to be connected to the rack 200. The device mounting portion 250 is located on the upright rack body 210 on a side of the rack 200 away from the power distribution cabinet 310, and extends along the upright rack body 210 in a slat shape, which has, for example, mounting holes thereon.

Of course, in other embodiments, depending on a size of the container body 100, computing power requirements and a power distribution mode, only one container power distribution information bracket arrangement S may be disposed in the container body 100, or three or even more container power distribution information bracket arrangements S may be disposed. In other embodiments, the container power distribution information bracket arrangements S may also be disposed in columns or in a matrix, and these are within the scope of protection of the present application.

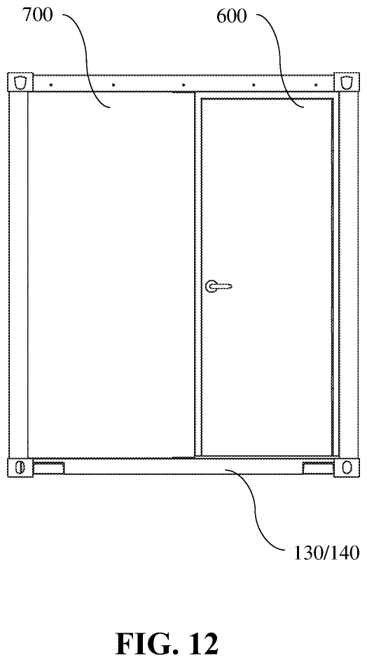

As shown in FIGS. 1, 11 and 12, the container body 100 of the server cluster container 1 of some embodiments of the present application includes a first side heat dissipation long edge 110, a second side heat dissipation long edge 120, a first side short edge 130, and a second side short edge 140, wherein the first side heat dissipation long edge 110 and the second side heat dissipation long edge 120 are symmetrically disposed along the length direction of the container body 100, and the first side short edge 130 and the second side short edge 140 are symmetrically disposed along the width direction of the container body 100.

The server cluster container 1 of some embodiments of the present application is a hexahedral shape formed by extending the first side heat dissipation long edge 110, the second side heat dissipation long edge 120, the first side short edge 130 and the second side short edge 140 to a height, which employs corner posts 11, bottom side beams 12 and top side beams 13 in combination with corner members 14 to constitute a main framework, making the structure robust, not susceptible to deformation or damage in loading, unloading and transportation processes, and easily loaded, unloaded and moved. A size of the server cluster container 1 may be the same as a current mainstream standard container size, such as 20-foot, 40-foot, etc. During loading, unloading and transportation, the same loading, unloading and transportation forms as those of standard containers may be employed. For example, the same loading and unloading equipment as that for standard containers, such as hoisting and forklifts, as well as the same transportation equipment such as land transportation vehicles and sea transportation ships may be used, which greatly reduces transportation costs. Of course, the server cluster container 1 of some embodiments of the present application may also be smaller than a standard container, which, when transported, is loaded in the standard container to avoid damage such as collision and displacement that may occur in transportation, loading and unloading processes. Further, one standard container may be loaded with one or more of the server cluster containers 1 of some embodiments of the present application.

The device row 400 formed by disposing the rack 200 and the power distribution cabinet 310 in a row is disposed along a direction in which the first side heat dissipation long edge 110 and the second side heat dissipation long edge 120 extend, two sides of the device row 400 respectively abut against the first side short edge 130 and the second side short edge 140, and the switch 320 is disposed at an end of the rack 200 away from the power distribution cabinet 310.

With reference to FIG. 3, the first side heat dissipation long edge 110 is provided with an air inlet structure, and the second side heat dissipation long edge 120 is provided with a cooling structure 900. The first side heat dissipation long edge 110 and the second side heat dissipation long edge 120 as disposed oppositely form an air flow to dissipate heat from and cool the servers in the container body 100.

In an embodiment, a shutter structure is provided on the first side heat dissipation long edge 110, and a cooling fan is provided on the second side heat dissipation long edge 120; alternatively, a dustproof mesh structure is provided on the first side heat dissipation long edge 110, and the cooling fan is provided on the second side heat dissipation long edge 120, wherein the dustproof mesh structure is, for example, a metal cut mesh or a metal woven mesh with mesh holes; alternatively, the shutter and dustproof mesh structures are provided on the first side heat dissipation long edge 110, and the cooling fan is provided on the second side heat dissipation long edge 120, both having good impurity prevention and wind cooling effects Some embodiments of the present application achieve a simple structure, low costs, and good heat dissipation effect by the oppositely disposed first side heat dissipation long edge 110 and second side heat dissipation long edge 120.

A maintenance passage 500 is provided between the first side heat dissipation long edge 110 and the device row 400, and door leaves 600 are provided at positions of the first side short edge 130 and the second side short edge 140 corresponding to the maintenance passage 500.

The device row 400 is disposed in parallel between the first side heat dissipation long edge 110 and the second side heat dissipation long edge 120, and the maintenance passage 500 between the first side heat dissipation long edge 110 and the device row 400 is used for the staff to conduct regular inspection, maintenance and upkeep for systems, devices, networks, and the like to ensure that they can normally operate, prevent failures and accidents, and improve the reliability and stability of the systems. The regular maintenance and upkeep can extend the service life of the systems, devices, networks, and the like, reduce the frequency and cost of replacement and repair, and optimize the systems, devices, networks, and the like, thereby improving system performance and efficiency and reducing resource wastes. Meanwhile, the maintenance passage can also be used to perform security inspection and protection on the systems, devices, networks, and the like to ensure the security and confidentiality of information. As can be seen, the maintenance passage plays an important role in ensuring the normal operation of the systems and improving the reliability, stability, performance and security of the systems.

The maintenance passage 500 of some embodiments of the present application is spacious and smooth, and at least one side of the first side short edge 130 and the second side short edge 140 corresponding to the maintenance passage 500 is provided with a door leaf 600. In this embodiment, door leaves 600 are respectively disposed on the first side short edge 130 and the second side short edge 140, and the staff may enter the maintenance passage 500 from one of the door leaves 600, inspect, maintain and service the systems, devices and networks in the container body 100, and then walk out from the other door leaf 600, which is convenient and quick and can effectively improve the working efficiency.

In an embodiment of the server cluster container 1 of some embodiments of the present application, positions of the first side short edge 130 and the second side short edge 140 corresponding to the rack 200 and between the rack 200 and the second side heat dissipation long edge 120 are closed walls 700. That is to say, the door leaves 600 disposed on the first side short edge 130 and the second side short edge 140 are half-open door leaves, and only the positions thereof corresponding to the maintenance passage 500 are openable/closeable door leaves, while where the first side short edge 130 and the second side short edge 140 do not correspond to the maintenance passage 500, there are closed walls sealed to top, which simplifies unnecessary design, and reduces safety hazards and the costs of maintenance and device manufacturing.

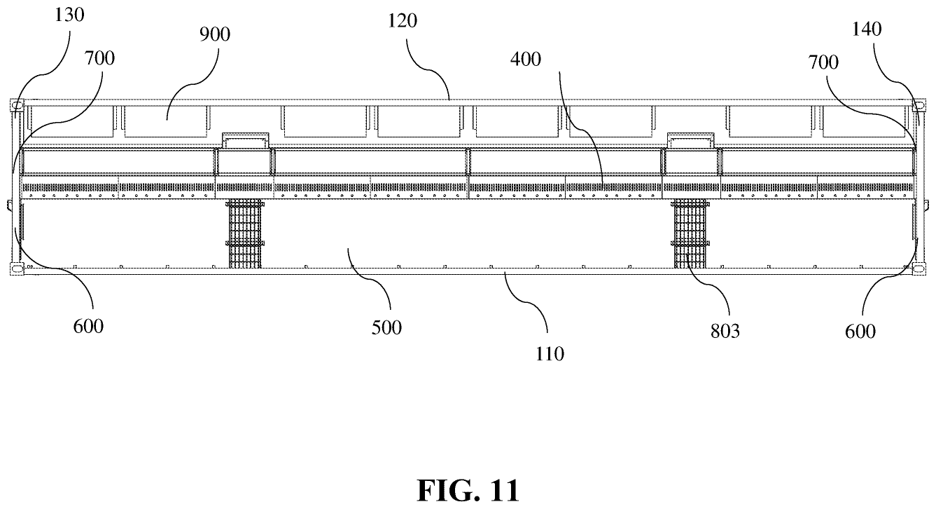

As shown in FIG. 7, the power distribution cabinet 310 includes a control and maintenance panel having a control switch 313 and status display modules 314 corresponding to each group of cooling structures 900. In this embodiment, with reference to FIGS. 3 and 11, the cooling structures 900 include 16 cooling fans, which are disposed in groups of four on the second side heat dissipation long edge 120. The control and maintenance panel of the power distribution cabinet 310 is provided with a control switch 313 corresponding to each group of cooling fans, and additionally with a status display module 314 corresponding to each of the cooling fans, which is beneficial to the staff's manipulation and observation of the cooling fans at any time.

The power distribution cabinet 310 includes a cabinet door 315, and at least a part of the control and maintenance panel is integrated outside the cabinet door 315. For example, the status display modules 314 are integrated to an exterior of the cabinet door 315, and the staff can check a working status of each cooling fan at any time without opening the cabinet door 315. Alternatively, the control switches 313 and the status display modules 314 are both integrated outside the cabinet door 315, which is beneficial to the staff's monitoring of the cooling fans of the cooling structures 900. Of course, modes of control and display of the control switches 313 and the status display modules 314 may be set as needed, and are not limited in the present application.

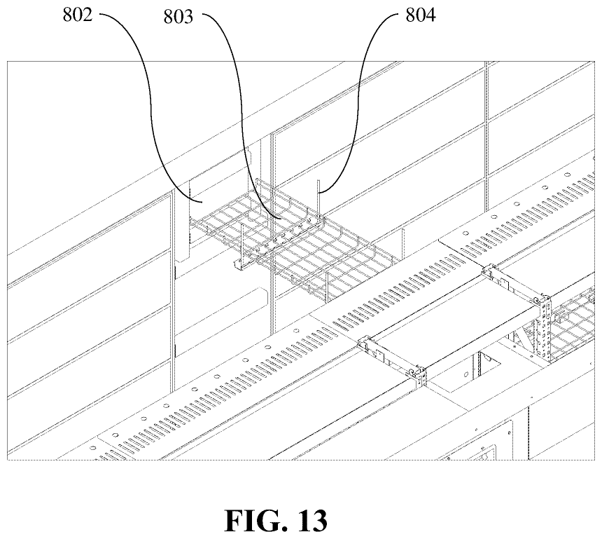

As shown in FIGS. 11 and 13, a position on the first side heat dissipation long edge 110 corresponding to the top of the power distribution cabinet 310 is provided with a cable inlet 802, and a cable tray 803 is disposed between the cable inlet 802 and the top of the power distribution cabinet 310. Power cables, after being introduced from the cable inlet 802, are connected to the power distribution cabinet 310 through the supporting of the cable tray 803. From a perspective inside the container body 100, for example, as viewed upward from the maintenance passage 500, the cable tray 803 spans the maintenance passage 500, and the cable tray 803 is located above within the maintenance passage 500 and between the power distribution cabinet 310 and the first side heat dissipation long edge 110. In a daily work process where the staff walk in the maintenance passage 500, they generally will not touch the cable tray 803, and the existence of the cable tray 803 will not affect the daily work of the staff either.

In detail, in this embodiment, the cable tray 803 is in a U-shape with two sides bent, and the power cables are connected to the power distribution cabinet 310 from the cable inlet 802 through the cable tray 803, which is safe and reliable. Two sides of the cable tray 803 are provided with baffle rods 804 for preventing the power cables in the cable tray 803 from falling from the sides. Preferably, the baffle rods 804 are disposed in pairs at the middle of the two sides of the cable tray 803, for example. In other embodiments, there may be a plurality of groups of baffle rods 804 as disposed in pairs and disposed at intervals along the two sides of the cable tray 803 to achieve a better anti-falling effect. The baffle rods 804 are made of a higher-strength material, such as a metal material, and may be shaped into a rod or a sheet. Alternatively, tops of the baffle rods 804 that are disposed oppositely may be bent and expanded outward to form introduction ports, which is beneficial to introduction of the power cables. Of course, the baffle rods 804 may also serve as a hoisting structure for hoisting the cable tray 803 to a top of the container body 100. In this embodiment, the cable tray 803 is a mesh structure, which enables timely observation of the load and is light in weight.

The containerized server cluster device of some embodiments of the present application includes a plurality of servers and the server cluster container 1, the servers are arranged and disposed on the rack 200 and connected to the power distribution cabinet 310 and the switch 320.

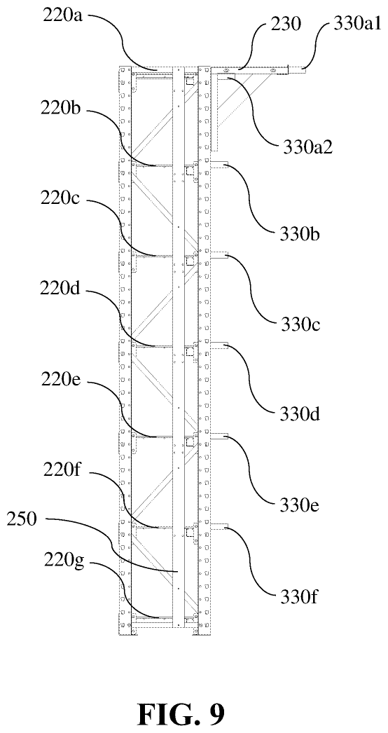

As shown in FIG. 9, in some embodiments of the present application, an extension baffle 230 is provided to extend a length of a layered partition 220 at an uppermost layer of the rack 200 along the width direction of the container body 100, so that a server can be laid flat thereon, which increases the number of integrated servers and can improve the computing power of the containerized server cluster device. Of course, in a case where the top space allows, servers located at the topmost layer may be normally arranged upright.

There are two power distributors on the layered partition at the topmost layer of the rack 200, one of which is connected with the server on the layered partition at the topmost layer of the rack 200, and the other of which is connected with a server on a layered partition at a layer directly below the same. The servers on the remaining layered partitions are connected with the power distributors on the layered partitions at respective upper layers.

Taking the rack 200 shown in FIG. 9 as an example, the rack 200 has 7 layered partitions 220a to 220g from top to bottom, wherein the layered partition 220a is located at a topmost layer, and the layered partition 220g is located at a bottommost layer. Servers are separately arranged and disposed on the layered partitions 220a to 220g. An extension baffle 230 is extended on and connected to the layered partition 220a at the topmost layer. An outer side of the extension baffle 230 is connected with a power distributor 330a1, and an outer side of the layered partition 220a at the topmost layer is connected with a power distributor 330a2. In addition, an outer side of the layered partition 220b is connected with a power distributor 330b, an outer side of the layered partition 220c is connected with a power distributor 330c, an outer side of the layered partition 220d is connected with a power distributor 330d, an outer side of the layered partition 220e is connected with a power distributor 330e, an outer side of the layered partition 220f is connected with a power distributor 330f, and an outer side of the layered partition 220g is not connected with a power distributor.

The servers arranged and disposed on the layered partition 220g are connected with the power distributor 330f at an upper layer, the servers arranged and disposed on the layered partition 220f are connected with the power distributor 330e at an upper layer, the servers arranged and disposed on the layered partition 220e are connected with the power distributor 330d at an upper layer, the servers arranged and disposed on the layered partition 220d are connected with the power distributor 330c at an upper layer, the servers arranged and disposed on the layered partition 220c are connected with the power distributor 330b at an upper layer, the servers arranged and disposed on the layered partition 220b are connected with the power distributor 330a2 at an upper layer, and the server arranged and disposed on the layered partition 220a is connected with the power distributor 330a1.

Referring to FIGS. 9 and 10, in order to enhance the overall strength of the rack 200, in an embodiment of the present application, the layered partition 220a at the topmost layer and the extension baffle 230 are in the shape of a plate body, and the staff cannot be timely aware of a working status of the servers located on the layered partition 220a at the topmost layer during maintenance. The containerized server cluster device of some embodiments of the present application further includes a top-layer device status feedback means for feeding back a top-layer device status. The top-layer device status feedback means is implemented in various ways such as software monitoring, hardware monitoring, remote monitoring and log monitoring.

In an embodiment of the present application, the top-layer device status feedback means employs a reflective mirror observation means, which can achieve real-time monitoring of the server status by means of a status indicator light of the server itself without investing any software or hardware in the server. The reflective mirror observation means is connected to the server disposed on the corresponding layered partition 220a at the topmost layer in the container body 100.

The number of the reflective mirror observation means is at least one, and each reflective mirror observation means corresponds to at least one server. For example, each reflective mirror observation means corresponds to 1, 2, or more servers, and the present application makes no limitation in this regard.

The reflective mirror observation means includes a plurality of feedback areas, each corresponding to at least one server disposed on the layered partition 220a at the topmost layer for feeding back a working status of the at least one server. There may be one or more reflective mirror observation means, which feeds back a working status of each server in real time, facilitating timely processing by the staff and ensuring the working efficiency of the device.

In other embodiments, the layered partition 220a at the topmost layer and the extension baffle 230 may likewise be made into a mesh shape to facilitate monitoring of their status by the staff.

In an embodiment of a server cluster container 2 of some embodiments of the present application, the server cluster container 2 includes a container body 100, a rack 200 disposed in the container body 100, and an electronic control system for connecting to servers supported on the rack 200, the electronic control system including a power distribution cabinet 310.

The racks 200 are disposed on two sides of the power distribution cabinet 310, the power distribution cabinet 310 includes side walls 311 adjacent to the racks 200, and the side walls 311 have cable outlets 311b disposed corresponding to partition layers of the racks 200. Power lines leading out from the cable outlets 311b supply power to servers on the partition layers of the racks 200.

There are a plurality of partition layers of the rack 200, each including a cross beam 221, and there are a plurality of cable outlets 311b of the power distribution cabinet 310, which are disposed in a one-to-one correspondence with the cross beams 221. The cable outlets 311b and the cross beams 221 that are in a one-to-one correspondence have the same vertical height. The power lines leading out from the cable outlets 311b can supply power to the servers on the partition layers of the rack 200 without being bent along a height direction of the container body 100.

Further, the cable outlets 311b and the cross beams 221 that are in a one-to-one correspondence are disposed in a staggered manner along a width direction of the container body 100, and the power lines leading out from the cable outlets 311b can supply power to the servers on the partition layers of the rack 200 without being bent along the width direction of the container body 100.

Power distributors 330 are transversely disposed on the cross beams 221, and line input ends of the power distributors 330 are opposite to the cable outlets 311b, so that the power lines leading out from the cable outlets 311b can be directly connected to the power distributors 330.

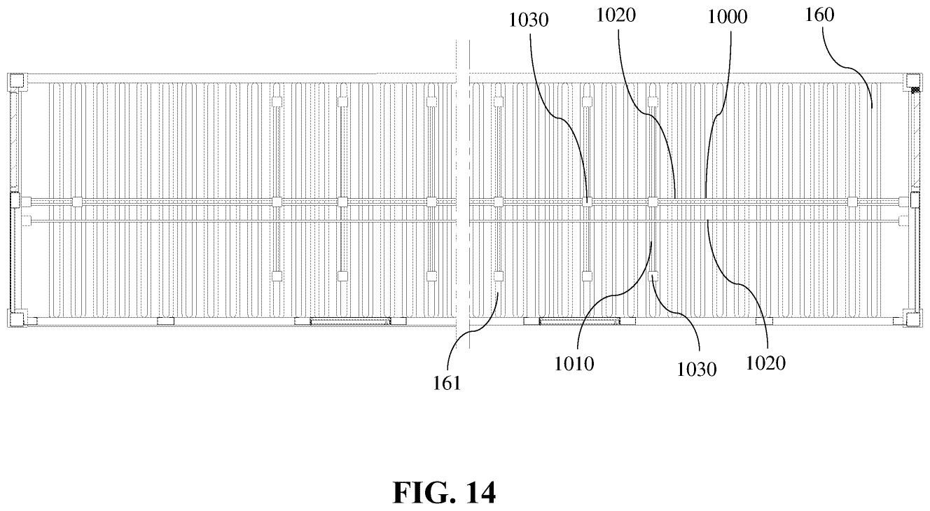

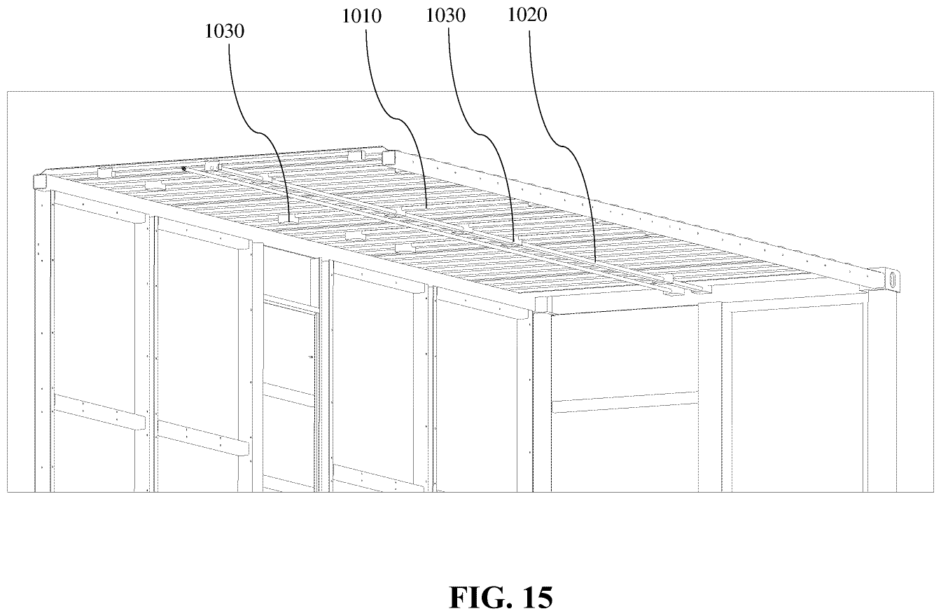

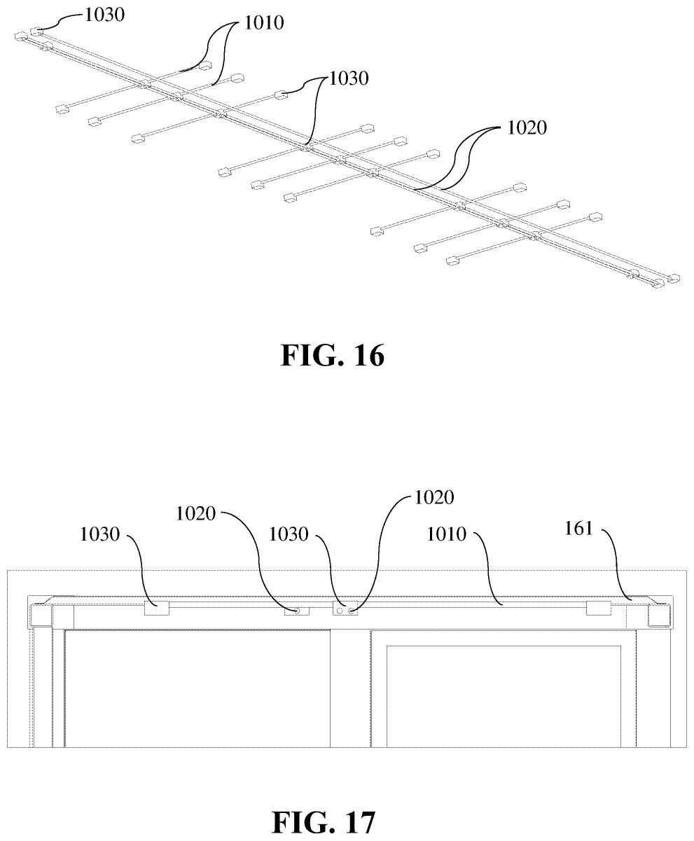

With reference to FIG. 1 in conjunction with FIGS. 14 to 17, in this embodiment, a server cluster container 3 of some embodiments of the present application includes a container body, a rack, and an electronic control system, and its structure and configuration may be the above embodiments. The server cluster container 3 of some embodiments of the present application further includes a top wiring conduit 1000 disposed on an inner top of the container body 100. The top wiring conduit 1000 is a hollow piping used for sleeved wiring of power lines and signal lines. In some embodiments of the present application, the sleeved routing of the lines can improve the service life of the cables, beautify wire wiring, ensure the safety and reliability of the cables, and also facilitate maintenance and management of the cables.

A set container of some embodiments of the present application employs corrugated plates as wall faces, which can enhance the structural strength, increase stability, prevent rust, reduce deadweight, etc. As shown, the container body 100 includes a top corrugated plate 160 including a longitudinal corrugated groove 161 protruding upward. The top wiring conduit 1000 includes a longitudinal conduit 1010, a transverse conduit 1020 and a junction box 1030, wherein the longitudinal conduit 1010 extends along a width direction of the container body 100, the transverse conduit 1020 extends along a length direction of the container body 100, and the junction box 1030 may be connected to the longitudinal conduit 1010, or to the transverse conduit 1020, or to both the longitudinal conduit 1010 and the transverse conduit 1020. In some embodiments of the present application, the longitudinal conduit extending along the width direction of the container body 100 and the junction box 1030 are at least partially located in the longitudinal corrugated groove 161 of the top corrugated plate 160, and a part of the longitudinal height of the top wiring conduit 1000 is absorbed by the longitudinal corrugated groove 161 of the top corrugated plate 160.

The transverse conduit 1020 is routed below the longitudinal conduit 1010. A decorative ceiling may be disposed on the top of the container body 100 and below the top wiring conduit 1000, which can completely hide the top wiring conduit 1000.

The longitudinal conduit 1010, the transverse conduit 1020 and the junction box 1030 are each provided in plural numbers according to needs.

In some embodiments of the present application, the wiring conduit is disposed between the top corrugated plate 160 of the container body 100 and the decorative ceiling, which makes full use of the characteristics of the plate material of the container body 100 to lay out conduits, reducing spaces occupied by lines and conduits in the container body 100, freeing up part of a height space of the container body, and providing a possibility of improving the integration performance of the entire device.

The junction box 1030 is for example connected to an end of the longitudinal conduit 1010 or an end of the transverse conduit 1020 for access or outlet of the signal or power lines. Alternatively, the junction box 1030 is connected to a junction of the longitudinal conduit 1010 and the transverse conduit 1020 for connection with the lines.

The junction box 1030, for example, may be used for connection with various devices in the container body 100, such as illumination lamps, sensors, cameras, and so on. Meanwhile, the junction box may also lead out a plurality of spare sockets, which are distributed on the side walls and top wall of the container body 100 for connecting various powered devices.

In some embodiments, the server cluster container 3 includes a top partition plate that is disposed opposite to the top corrugated plate 160, and the top wiring conduit 1000 is located between the top partition plate and the top corrugated plate 160. The top partition plate provides concealment and protection for the top wiring conduit 1000. In some embodiments, an upper side of the top partition plate is further provided with a heat-insulating layer for isolating external heat from entering an area below the top partition plate. The heat-insulating layer employs heat-insulating materials. Further, a foaming material, such as a polyurethane foaming material, is filled between the heat-insulating layer and the top corrugated plate 160 to further enhance the heat insulation effect.

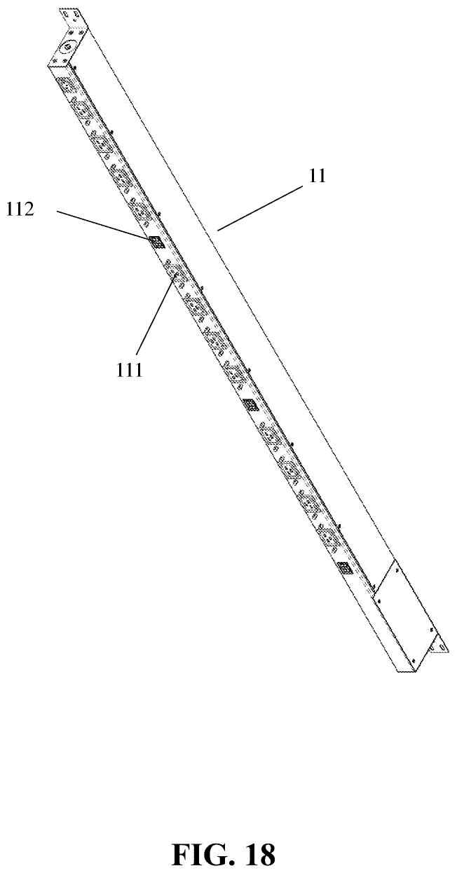

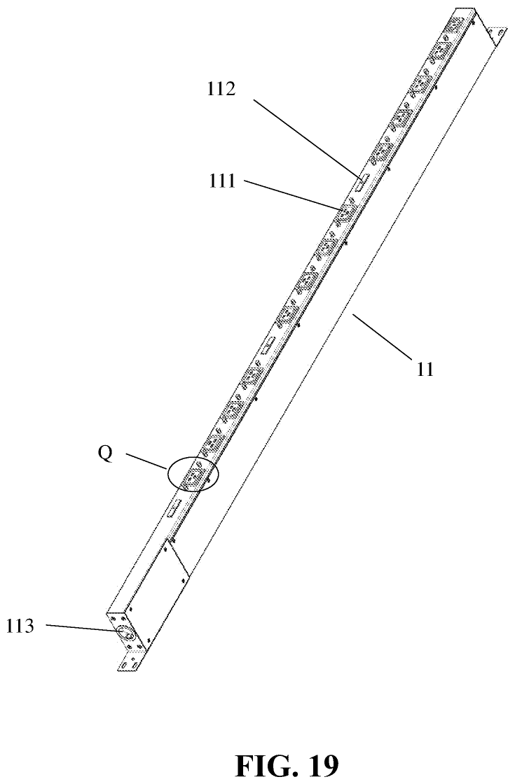

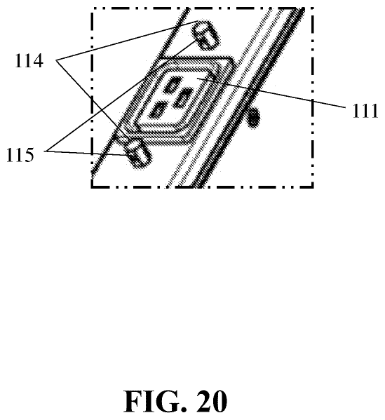

As shown in FIGS. 18 to 20, which are schematic structural diagrams of a power distributor in the present application, the power distributor 11 includes a plurality of sockets 111, indicator lights 112 corresponding to the sockets (which, for example, may be LED lights or digital tubes, and the present application makes no limitation in this regard), and a line entry hole 113. The power distribution cabinet in the present application supplies power to the power distributor through the line entry hole 113, and the servers draw power through the sockets 111. The number of indicator lights and the number of sockets 111 may correspond one to one, or one indicator light may correspond to two or more sockets to display power supply of the corresponding sockets. Furthermore, the power distributor 11 is further provided with anti-disconnect structures. For example, the anti-disconnect structures 114 may be columnar structure, and two sides of each socket correspond to two of the columnar structures. Exemplarily, the columnar structures are provided with through holes 115, through which a structure for preventing a plug inserted into the socket from disconnecting may be fitted and mounted. Exemplarily, this structure for preventing the plug inserted into the socket from disconnecting includes a first fixing end, a second fixing end and a main body, wherein the first fixing end is connected to a columnar structure on a side of the socket, the second fixing end is connected to a columnar structure on the other side of the socket, and the main body is used for preventing the plug from disconnecting.

Exemplarily, this structure for preventing the plug inserted into the socket from disconnecting may be an iron wire, an end of which is fixed through a through hole of one of the columnar structures, the other end of which is fixed through a through hole of the other columnar structure, and the main body of which spans the plug, achieving the anti-disconnect effect on the plug. Furthermore, this structure for preventing the plug inserted into the socket from disconnecting may also be a cable tie, and the present application makes no limitation in this regard.

Of course, the present application may have many other embodiments. Without departing from the spirit and essence of the present application, those skilled in the art may make various corresponding changes and modifications according to the present application, but these corresponding changes and modifications should all fall within the scope of protection of the attached claims of the present application.

### Industrial Applicability

A server cluster container of the present application includes a container body, and a rack disposed in the container body, and an electronic control system for connecting servers supported on the rack, the electronic control system including a power distribution cabinet and a switch, and the container body including a top corrugated plate and a top wiring conduit that is at least partially located in a corrugated groove of the top corrugated plate. A containerized server cluster device of the present application includes a plurality of servers and the above server cluster container, and the servers are arranged and disposed on the rack and connected to the power distribution cabinet. The server cluster container of the present application and a containerized computer cluster device including this container improve the working efficiency of a server cluster through a reasonable layout of the power distribution cabinet, rack and switch of the container. The present application makes full use of the characteristics of the plate material of the container body to lay out conduits, reducing spaces occupied by lines and conduits in the container body, freeing up part of a height space of the container body, and providing a possibility of improving the integration performance of the entire device.

1. A server cluster container, comprising a container body, a rack disposed in the container body, and an electronic control system for connecting servers supported on the rack, the electronic control system comprising a power distribution cabinet and a switch.

2. The server cluster container according to claim 1, wherein the container body comprises a top corrugated plate and a top wiring conduit, and at least a part of the top wiring conduit is located in a corrugated groove of the top corrugated plate.

3. The server cluster container according to claim 2, wherein the top wiring conduit comprises a longitudinal conduit and a transverse conduit that are cross-distributed, the longitudinal conduit is at least partially located in the corrugated groove of the top corrugated plate, or the transverse conduit is at least partially located in the corrugated groove of the top corrugated plate.

4. The server cluster container according to claim 3, wherein an extension direction of the longitudinal conduit is consistent with an extension direction of the corrugated groove, and the longitudinal conduit is disposed in the corrugated groove.

5. The server cluster container according to claim 3, wherein the top wiring conduit further comprises a junction box connected to the longitudinal conduit and/or the transverse conduit, and the junction box is at least partially located in the corrugated groove; and
wherein the junction box is connected to an end of the longitudinal conduit, or the junction box is connected to an intersection of the longitudinal conduit and the transverse conduit, or the junction box is connected to an end of the transverse conduit.

6. (canceled)

7. The server cluster container according to claim 1, wherein the switches are disposed at two ends of the racks away from the power distribution cabinet, and signal lines of the servers supported on the racks are connected to the switches.

8. The server cluster container according to claim 1, wherein the rack comprises a plurality of partition layers for supporting the servers, each correspondingly provided with at least one switch;
wherein the signal lines of the servers supported on each of the partition layers are connected to at least one switch corresponding to the partition layer; and
wherein the partition layer comprises a cross beam provided with a cable management slot, through which the signal lines of the servers supported on the partition layer are connected to the switch.

9-10. (canceled)

11. The server cluster container according to claim 8, wherein the partition layer includes a first cross beam and a second cross beam that are disposed at intervals in a horizontal direction, the first cross beam is provided with a first cable management slot, through which the signal lines of a part of the servers supported on the partition layer are connected to the switch, and the second cross beam is provided with a second cable management slot, through which the signal lines of the other part of the servers supported on the partition layer are connected to the switch.

12. The server cluster container according to claim 1, wherein the rack comprises upright rack bodies that disposed oppositely and a plurality of layered partitions connected between the upright rack bodies, and at least a part of the layered partitions is in a mesh shape; and
wherein the power distribution cabinet includes a side wall that is adjacent to the upright rack body and has a plurality of cable outlets, and the layered partitions comprise cross beams, and at least one of the cable outlets is disposed corresponding to at least one of the cross beams.

13. (canceled)

14. The server cluster container according to claim 12, wherein the cable outlets are disposed corresponding to the cross beams lower than a height of the power distribution cabinet;
wherein a top of the power distribution cabinet has a top cable port disposed corresponding to the cross beam higher than the height of the power distribution cabinet; and
wherein the cable outlets and the corresponding cross beams are disposed in a staggered manner along a width direction of the box body.

15-16. (canceled)

17. The server cluster container according to claim 12, wherein the electronic control system further comprises a plurality of power distributors disposed on the cross beams, and line input ends of the power distributors face a direction of the power distribution cabinet.

18. The server cluster container according to claim 12, wherein the rack further comprises an extension baffle disposed on an outer side of at least one of the layered partitions along the width direction of the container body;
wherein the layered partitions comprise high layered partitions higher than or equal to a set height and low layered partitions lower than the set height, and the extension baffle is disposed on an outer side of at least one of the high layered partitions;
wherein the extension baffle is disposed on the outer side of the high layered partition at a topmost layer; and
wherein the extension baffle comprises a baffle beam, and the electronic control system further comprises a power distributor disposed on the baffle beam.

19-21. (canceled)

22. The server cluster container according to claim 18, wherein the power distribution cabinet comprises a side wall that is adjacent to the upright rack body and has a plurality of cable outlets, a top of the power distribution cabinet has a top cable port, and line input ends of the power distributors face a direction of the power distribution cabinet.

23. The server cluster container according to claim 12, wherein the rack further comprises a device mounting portion located on a side of the rack away from the power distribution cabinet; and
wherein the device mounting portion is located on the upright rack body on the side of the rack away from the power distribution cabinet, and extends along the upright rack body in the shape of a slat.

24. (canceled)

25. The server cluster container according to claim 1, wherein the rack and the power distribution cabinet are disposed in a row along a length direction of the container body to form a device row, and the racks are symmetrically configured on two sides of the power distribution cabinet; and
wherein the container body comprises a first side heat dissipation long edge and a second side heat dissipation long edge that symmetrically extend along the length direction, and a maintenance passage is formed between the first side heat dissipation long edge and the device row.

26. (canceled)

27. The server cluster container according to claim 25, wherein the power distribution cabinet comprises a control and maintenance panel having a control switch and status display modules corresponding to each group of cooling structures; and
wherein the power distribution cabinet comprises a cabinet door, and at least a part of the control and maintenance panel is integrated outside the cabinet door.

28. (canceled)

29. The server cluster container according to claim 25, wherein a position on the first side heat dissipation long edge corresponding to a top of the power distribution cabinet is provided with a cable inlet;
wherein a cable support structure is disposed between the top of the power distribution cabinet and the cable inlet; and
wherein the cable support structure comprises a cable tray for supporting power cables and a hoisting structure for hoisting the cable tray to a top of the container body.

30-31. (canceled)

32. A containerized server cluster device, comprising a plurality of servers, wherein the containerized server cluster device further comprises the server cluster container according to any one of claim 1, and the servers are arranged and disposed on the rack and connected to the power distribution cabinet.

33. The containerized server cluster device according to claim 31, wherein a server located on a layered partition at a topmost layer of the rack is laid flat.

34. The containerized server cluster device according to claim 32, wherein two rows of power distributors are present on the layered partition at the topmost layer of the rack, the server on the layered partition at the topmost layer of the rack is connected with one row of the power distributors at the topmost layer, and the servers on the remaining layered partitions are connected with the power distributors on the layered partitions at respective upper layers.
